(19) United States
(12) Patent Application Publication
(10) Pub. No.: US 2017/0250118 A1
(43) Pub. Date: Aug. 31, 2017

(54) ELECTRONIC DEVICE, ALTIMETER, ELECTRONIC APPARATUS, AND MOVING OBJECT

(71) Applicant: SEIKO EPSON CORPORATION, Tokyo (JP)

(72) Inventor: Shinichi YOTSUYA, Chino-shi (JP)

(73) Assignee: SEIKO EPSON CORPORATION, Tokyo (JP)

(21) Appl. No.: 15/433,220

(22) Filed: Feb. 15, 2017

(30) Foreign Application Priority Data
Feb. 26, 2016 (JP) 2016-036339

(51) Int. Cl. H01L 23/04; G01C 5/06; G01L 19/06

(52) U.S. Cl. CPC H01L 23/041; G01L 19/0654; G01C 5/06

(57) ABSTRACT

An electronic device includes a package including an opening, and a cavity communicating with the opening, a pressure sensor element disposed in the cavity, and a waterproof unit is disposed in the package so as to cover the opening, in which the waterproof unit includes a through hole that is a separate body from the package, blocks passing of liquid, and permits passing of gas from an outside of the package into an inside of the cavity.

### BACKGROUND

1. Technical Field

The present invention relates to an electronic device, an altimeter, an electronic apparatus, and a moving object.

2. Related Art

In the related art, a configuration according to JP-A-2015-143634 is known as a pressure sensor (electronic apparatus) having waterproofness. A pressure sensor of JP-A-2015-143634 includes a package, a pressure sensor accommodated within the package, and a gel filled in the package so as to cover the pressure sensor, and pressure outside the package is transmitted to the pressure sensor through the gel. According to the configuration, since adhesion of moisture to the pressure sensor is prevented by the gel, it is possible to exhibit the waterproofness.

However, in a configuration of JP-A-2015-143634, it is very unlikely to densely fill the package with the gel without generating bubble within the package, and know-how is also necessary. When the bubble (void) is generated within the gel, since pressure outside the package and pressure transmitted to the pressure sensor are different from each other, there is a problem that pressure sensing accuracy is lowered.

### SUMMARY

An advantage of some aspects of the invention is to provide an electronic device, an altimeter having high-reliability, an electronic apparatus, and a moving object, including the electronic device, capable of easily exhibiting waterproofness.

The advantage can be achieved by the following configurations.

An electronic device according to an aspect of the invention includes: a package that includes an opening, and an accommodation space communicating with the opening; an electronic component that is disposed in the accommodation space; and a waterproof unit that is disposed in the package so as to cover the opening, in which the waterproof unit is a separate body from the package, blocks passing of liquid, and permits passing of gas from an outside of the package into an inside of the accommodation space.

With this configuration, by providing only the waterproof unit, the electronic device capable of easily exhibiting the waterproofness can be obtained.

In the electronic device according to the aspect of the invention, it is preferable that the waterproof unit includes a through hole that blocks the passing of liquid and permits the passing of gas from the outside of the package into the inside of the accommodation space.

With this configuration, the waterproof unit can be simply configured.

In the electronic device according to the aspect of the invention, it is preferable that a plurality of through holes are disposed in the waterproof unit, and in which disposition density of the through holes positioned on an edge portion of the opening is higher than that of the through holes positioned on a center portion of the opening of the waterproof unit, in a plan view of the opening.

With this configuration, it is possible to reduce decrease of a mechanical strength on a center portion of the waterproof unit, and it is possible to reduce deflection of the waterproof unit.

In the electronic device according to the aspect of the invention, it is preferable that a minimum width of the through hole is equal to or greater than 0.1 μm, and equal to or less than 10 μm.

With this configuration, higher waterproofness can be obtained.

In the electronic device according to the aspect of the invention, it is preferable that a center of the electronic component is disposed by being deviated from a center of the opening, in a plan view of the opening.

With this configuration, it is possible to improve the degree of freedom in a device design.

In the electronic device according to the aspect of the invention, it is preferable that the package includes a first member, and a second member fixed to the first member and the waterproof unit is fixed to the package by being pinched between the first member and the second member.

With this configuration, the package of the waterproof unit can be easily fixed.

In the electronic device according to the aspect of the invention, it is preferable that the electronic component is a pressure sensor element.

With this configuration, for example, it is possible to use the electronic device as a water pressure sensor (depth meter).

An altimeter according to another aspect of the invention includes the electronic device according to the aspect of the invention.

With this configuration, the altimeter having high reliability can be obtained.

An electronic apparatus according to still another aspect of the invention includes the electronic device according to the aspect of the invention.

With this configuration, the electronic apparatus having high reliability can be obtained.

A moving object according to yet another aspect of the invention includes the electronic device according to the aspect of the invention.

With this configuration, the moving object having high reliability can be obtained.

### BRIEF DESCRIPTION OF THE DRAWINGS

The invention will be described with reference to the accompanying drawings, wherein like numbers reference like elements.

FIG. 1 is a sectional view illustrating an electronic device according to a first embodiment of the invention.

FIG. 2 is a plan view of a flexible wire substrate included in the electronic device illustrated in FIG. 1.

FIG. 3 is a plan view and a sectional view of a waterproof unit included in the electronic device illustrated in FIG. 1.

FIG. 4 is a sectional view for explaining a manufacturing method of the waterproof unit illustrated in FIG. 3.

FIG. 5 is a sectional view for explaining a manufacturing method of the waterproof unit illustrated in FIG. 3.

FIG. 6 is a sectional view for explaining a manufacturing method of the waterproof unit illustrated in FIG. 3.

FIG. 7 is a sectional view for explaining a manufacturing method of the waterproof unit illustrated in FIG. 3.

FIG. 8 is a plan view illustrating a modification example of the waterproof unit illustrated in FIG. 3.

FIG. 9 is a sectional view of a pressure sensor element included in the electronic device illustrated in FIG. 1.

FIG. 10 is a plan view illustrating a sensor unit included in the pressure sensor element illustrated in FIG. 9.

FIG. 11 is a diagram illustrating a bridge circuit including the sensor unit illustrated in FIG. 10.

FIG. 12 is a sectional view illustrating an electronic device according to a second embodiment of the invention.

FIG. 13 is a perspective view illustrating an example of an altimeter according to the invention.

FIG. 14 is a front view illustrating an example of an electronic apparatus according to the invention.

FIG. 15 is a perspective view illustrating an example of a moving object according to the invention.

### DESCRIPTION OF EXEMPLARY EMBODIMENTS

Hereinafter, an electronic device, an electronic apparatus, and a moving object according to the invention will be described based on embodiments illustrated in the attached drawings.

### First Embodiment

First, an electronic device according to a first embodiment of the invention will be described.

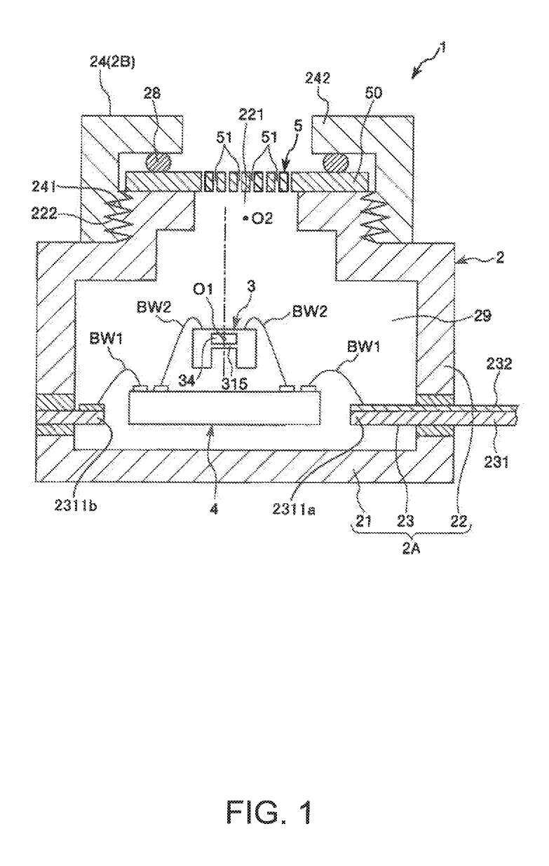

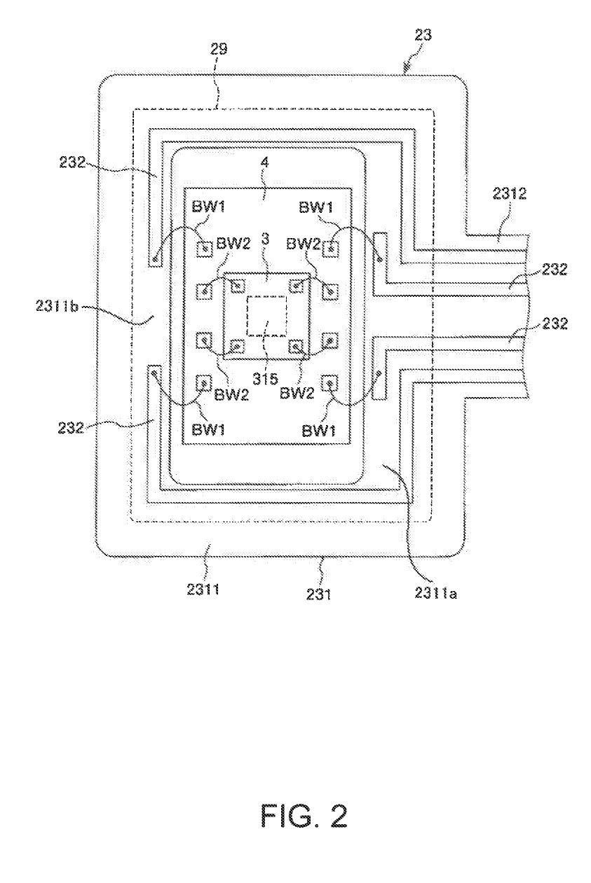

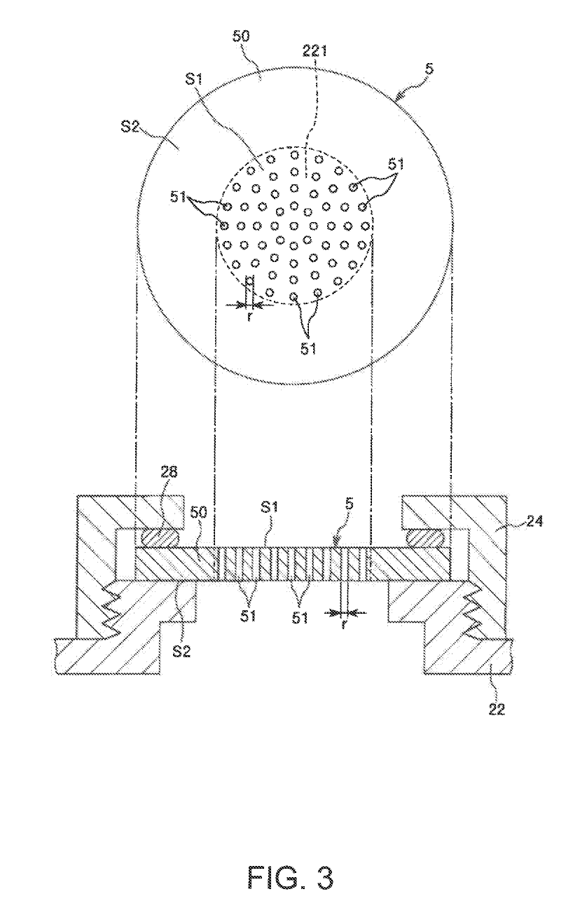

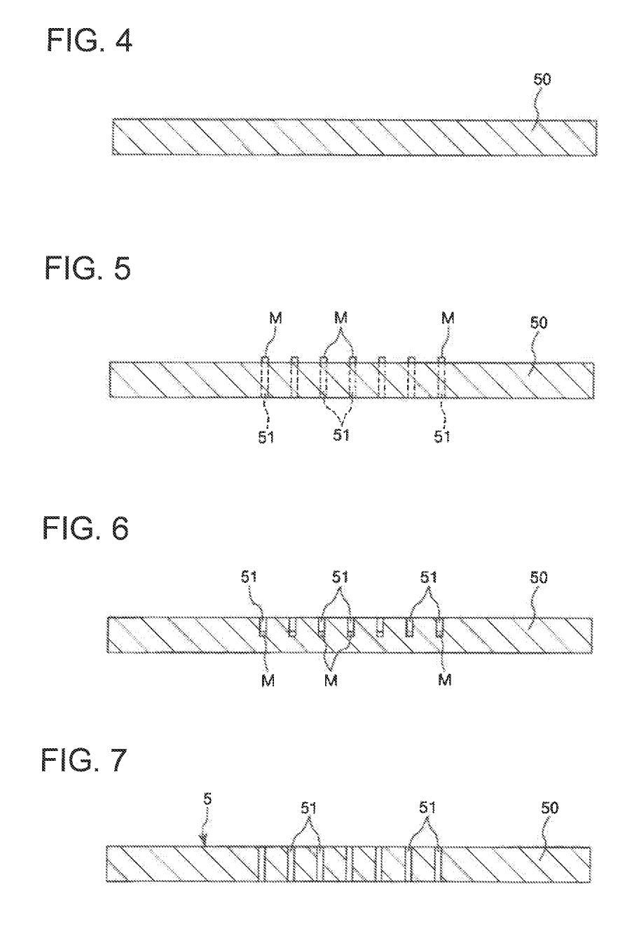

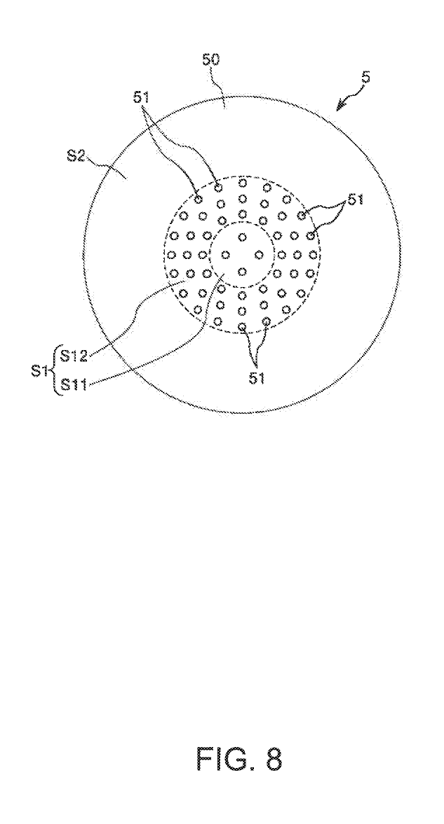

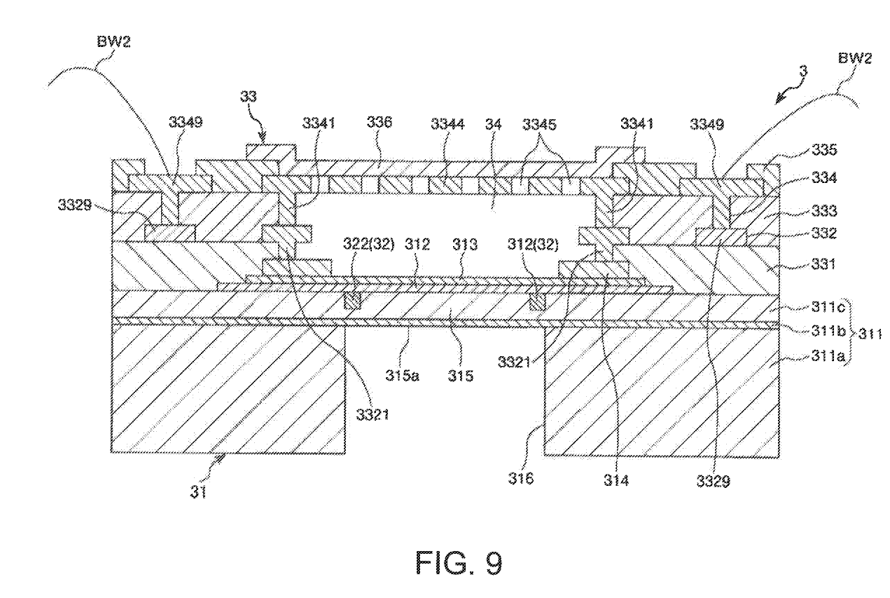

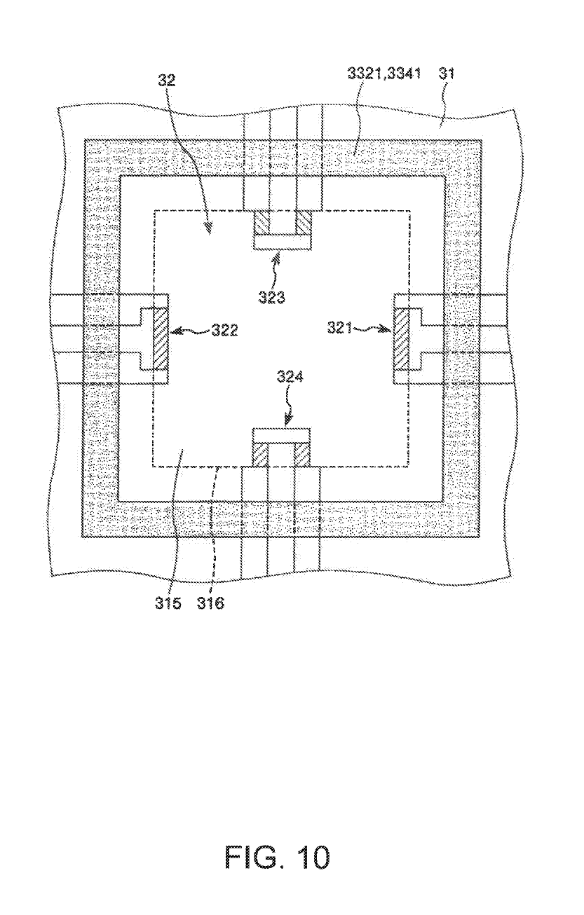

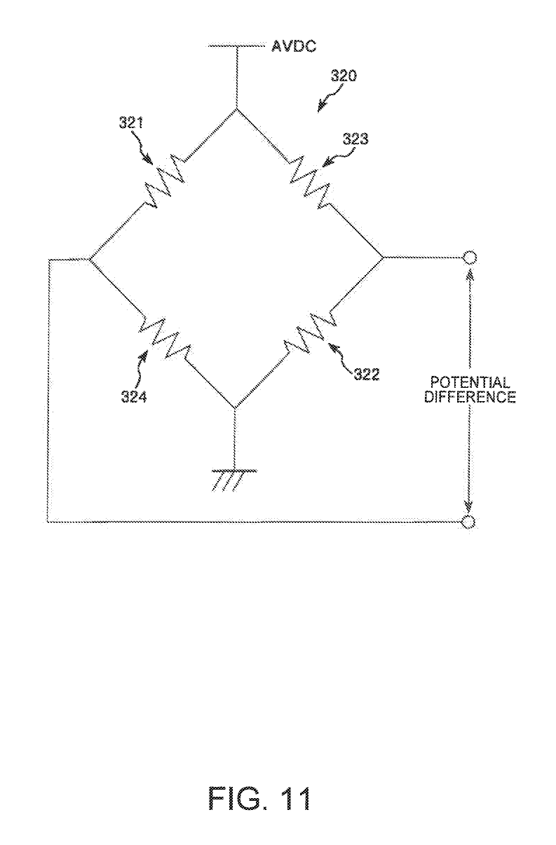

FIG. 1 is a sectional view illustrating an electronic device according to a first embodiment of the invention. FIG. 2 is a plan view of a flexible wire substrate included in the electronic device illustrated in FIG. 1. FIG. 3 is a plan view and a sectional view of a waterproof unit included in the electronic device illustrated in FIG. 1. FIG. 4 to FIG. 7 are sectional views for explaining a manufacturing method of the waterproof unit illustrated in FIG. 3, respectively. FIG. 8 is a plan view illustrating a modification example of the waterproof unit illustrated in FIG. 3. FIG. 9 is a sectional view of a pressure sensor element included in the electronic device illustrated in FIG. 1. FIG. 10 is a plan view illustrating a sensor unit included in the pressure sensor element illustrated in FIG. 9. FIG. 11 is a diagram illustrating a bridge circuit including the sensor unit illustrated in FIG. 10. In the following description, for convenience of description, an upper side in FIG. 1 is referred to as a “upper”, and a lower side is referred to as a “lower”.

An electronic device 1 illustrated in FIG. 1 is the pressure sensor having the waterproofness which can detect various pressures such as air pressure and water pressure. The electronic device 1 includes a package 2, a pressure sensor element (electronic component) 3 accommodated in the package 2, an IC chip (electronic component) 4, and a waterproof unit 5 that covers an opening of the package 2. Hereinafter, these parts will be sequentially described.

### Package

The package 2 includes the pressure sensor element 3 accommodated in a cavity (internal space) 29 formed therein. The package 2 includes a base 21, a housing 22, and a flexible wire substrate 23, and is configured by a first member 2A that includes the cavity 29 therein and a second member 2B that includes a cap 24 fixed to the housing 22. A planar shape of the package 2 is a square shape on the lower side (base 21) thereof, and a circular shape on the upper side (screw portion between housing 22 and cap 24).

The first member 2A is configured by pinching the flexible wire substrate 23 between the base 21 and the housing 22, and bonding these parts each other by an adhesive or the like. In addition, an opening 221 connected to the cavity 29 is formed on an upper surface of the housing 22, and a screw portion 222 screwed with the cap 24 is formed on an outer peripheral surface of the housing 22.

Constituent material of the base 21 and the housing 22 is not particularly limited. For example, various ceramic materials such as alumina, silica, and titania, various resin materials such as polyethylene, polyamide, polyimide, polycarbonate, acrylic resin, ABS resin, and epoxy resin, and metal materials such as aluminum, nickel, chromium, magnesium, titanium, and stainless steel, can be mentioned. Among them, it is preferable to use various kinds of ceramics in viewpoint of increasing a mechanical strength. In addition, it is preferable to use various metal materials (conductive material) in viewpoint of improving sensing accuracy of the pressure sensor element 3 by blocking noises from outside. When the metal material is used, it is preferable to use passive metals and an alloy (specifically, alloy of aluminum, chromium, titanium, stainless steel, or the like) including the passive metals in viewpoint of excellent corrosion resistance (that is, hard to rust).

In addition, the flexible wire substrate 23 has a function to support the pressure sensor element 3 within the package 2, and extract a wire connected to the pressure sensor element 3 to outside of the package 2. The flexible wire substrate 23 includes a base substrate 231 having flexibility and a wire 232 formed on the base substrate 231.

As illustrated in FIG. 2, the base substrate 231 includes a base 2311 disposed in the cavity 29, and a belt-shaped strip 2312 protruded from the base 2311 and extracted up to the outside of the package 2. The constituent material of the base substrate 231 is not particularly limited, if it has the flexibility. For example, polyimide, polyethylene terephthalate (PET), polyethylene naphthalate (PEN), polyethersulfone (PES), and the like can be mentioned, and can be used by combining one kind or two or more kinds of them.

The wire 232 is disposed over the inside and outside of the package 2. In addition, the wire 232 is electrically connected to an IC chip 4 through a bonding wire BW1. In addition, the IC chip 4 is supported while being suspended on the flexible wire substrate 23 by the bonding wire BW1. In this embodiment, four wires 232 and four bonding wires BW1 are provided. However, the number of the wires 232 and the bonding wires BW1 is not particularly limited. The number of the wires 232 and the bonding wires BW1 can be appropriately set according to the number of terminals of the IC chip 4.

The cap 24 is formed in a tubular shape, and includes a screw portion 241 screwed with the screw portion 222 of the housing 22 on an inner periphery surface thereof. Then, the cap 24 is fixed to the housing 22 in a screw manner. In addition, the cap 24 includes a flange 242 of an annular shape (ring shape) protruded toward the inner periphery on an upper end portion thereof. The flange 242 is used to pinch the waterproof unit 5 between the housing 22 and the flange 242.

The constituent material of the cap 24 is not particularly limited. For example, it is possible to use the same material as the constituent material of the base 21 and the housing 22 described above. In addition, the constituent material of the cap 24 and the constituent material of the base 21 and the housing 22 may be the same material, or may be different materials. Specifically, as the constituent material of the cap 24, it is preferable to use various resin materials such as polyethylene, polyamide, polyimide, polycarbonate, acrylic resin, ABS resin, and epoxy resin. With this, it is possible for the cap 24 to easily manufacture by injection molding, and it is possible to reduce a manufacturing cost.

### Waterproof Unit

As illustrated in FIG. 1, the waterproof unit 5 is formed in a plate shape, and provided to cover the opening (opening 221) of the package. In addition, the waterproof unit 5 is fixed to the package 2 by being pinched between an upper surface of the housing 22 and a lower surface of the flange 242 of the cap 24. By adopting the fixing method, it is possible to fix the waterproof unit 5 to the package 2 relatively easily and more reliably. In this manner, by implementing the waterproof unit 5 as a separate body from the package 2, since it is unlikely to restrict the configuration (shape and constituent material) of the waterproof unit 5 and the package 2, the degree of freedom in a design of the waterproof unit 5 and the package 2 is improved.

The waterproof unit 5 is configured to block passing of water (liquid) and permit passing of air (gas) from outside of the package 2 into the cavity 29. Therefore, it is possible to protect the pressure sensor element 3 within the cavity 29 from the water, and it is possible to detect pressure applied to the electronic device 1 by the pressure sensor element 3. By exhibiting the waterproofness with the waterproof unit 5, the electronic device 1 having the waterproofness can be more easily obtained, compared to a configuration using the gel in the related art. The gas of which the passing is permitted is not limited to the air, and the liquid of which the passing is blocked is not limited to the water.

In addition, in the embodiment, by providing an O-ring (packing) 28 between the flange 242 and the waterproof unit 5, air tightness of the package 2 is improved. Therefore, it is possible to effectively reduce invasion of water from a portion between the waterproof unit 5 and the package 2 into the cavity 29. However, furthermore, the O-ring 28 may be provided between the housing 22 and the waterproof unit 5, or may be omitted if not necessary.

The waterproof unit 5 includes a plate shaped base plate 50 and a plurality of through holes 51 that pass through upper and lower surfaces of the base plate 50. Then, each of the through holes 51 has a small diameter which can approximately block the passing of water and permit the passing of gas. According to the configuration, it is possible to simply configure the waterproof unit 5.

Constituent material of the base plate 50 is not particularly limited. For example, it is possible to use silicon. By using the silicon, manufacturing accuracy of the base plate 50 becomes excellent, and the through holes 51 are easily formed. In addition, a thickness of the base plate 50 is not particularly limited. However, for example, it is possible that the thickness of the base plate 50 is approximately equal to or greater than 100 μm, and equal to or less than 500 μm. By implementing the thickness, while sufficiently increasing a mechanical strength of the base plate 50, it is possible to prevent excessive thickening of the base plate 50. Furthermore, it is also possible to implement an etching time relatively shorter than a time (for example, metal assist etching time, which will be described below) required for formation of the through holes 51.

In addition, although not illustrated, for example, wastewater treatment is performed with a fluorine compound having a trifluoromethyl group (—CF3) on the upper surface of the base plate 50. In this manner, by processing the upper surface of the base plate 50 by the wastewater treatment, since it is possible to more accurately control a contact angle of the water on the upper surface of the base plate 50, a diameter of the through holes 51 can be easily determined.

In addition, as illustrated in FIG. 3, the base plate 50 includes a first region S1 that disposed in a center portion (portion overlapping with opening 221 in plan view) thereof, and includes the through holes 51 formed thereon, and a frame shaped second region S2 that is disposed outside the first region S1, and pinched between the housing 22 and the cap 24 without forming the through holes 51. As described above, since the through holes 51 are not formed on the second region S2, it is possible to reduce decrease of a mechanical strength of the second region S2, and it is possible to reduce breakage (occurrence of cracks or the like) of the base plate 50.

In a plan view, a plurality of the through holes 51 are approximately evenly distributed and arranged on the first region S1. In addition, each of the through holes 51 has a circular horizontal cross-sectional shape. In addition, each of the through holes 51 has a diameter (width) r thereof that is approximately constant along an extension direction, and has a straight vertical cross-sectional shape.

However, disposition of the through holes 51 is not particularly limited, and, for example, may be unevenly arranged. In addition, a vertical cross-sectional shape of the through holes 51 is not particularly limited, and, for example, the diameter r may be a taper shape which gradually increases or decreases from an upper surface of the waterproof unit 5 toward a lower surface, and may be a sandglass of which the diameter r of the center portion in the extension direction is the smallest and the diameter r gradually increases toward both sides (upper side and lower side) from the center portion. In addition, a horizontal cross-sectional shape of the through holes 51 is formed as a circular shape. However, the horizontal cross-sectional shape of the through holes 51 is not particularly limited, and may be a polygon such as a quadrangle and a triangle, or may be an ellipse, an oval, and an irregular shape. In addition, the through holes 51 having different vertical cross-sectional shapes and horizontal cross-sectional shapes may be mixed.

If the passing of water is blocked and the passing of air is permitted, the diameter r (minimum value of diameter when vertical cross-sectional shape of through holes 51 is taper shape or the like) of the through holes 51 is not particularly limited. For example, it is preferable that the diameter r is equal to or greater than 0.1 μm, and equal to or less than 10 μm. With this, it is possible to implement the through holes 51 which can more reliably block the passing of water. In addition, it is preferable that a diameter r is small enough to realize approximately 10 atm water resistant (that is, it is possible to block passing of water even in a state of 100 m underwater). By realizing the 10 atm water resistant, since the waterproofness which can withstand, for example, free diving or the like can be exhibited, it is possible to implement the electronic device 1 having excellent convenience.

Here, in 1 to 10 air pressures, since a contact angle of water on the upper surface of the base plate 50 is approximately 120°, it is necessary to set the diameter r of the through holes 51 approximately equal to or less than 0.144 μm in order to realize the 10 atm water resistant. As illustrated in FIG. 3, when a determination method of the diameter r is simply described, where D=diameter, P=pressure, σ=surface tension, and θ=contact angle, a relationship of D=(−4 σ cos θ)/P is obtained from a mercury injection method. Therefore, when the surface tension of water (σ≅72 dyn/cm: 20° C.), pressure (P=10 atm), and a contact angle (0=120°) are substituted into this equation, it is possible to obtain D=0.144 μm. As a reference, for several contact angles θ, values of D obtained by realizing the 10 atm water resistant are represented in the following Table 1.

TABLE 1

| θ (°) | D (μm) |
|---|---|
| 100 | 0.05 |
| 110 | 0.099 |
| 120 | 0.144 |
| 130 | 0.185 |
| 140 | 0.221 |
| 150 | 0.149 |
| 160 | 0.271 |
| 170 | 0.284 |
| 180 | 0.288 |

For example, it is preferable that the through holes 51 are formed by a metal assisted etching. The metal assisted etching is suitable for forming a small through hole having a long diameter. With this, it is possible to form through holes 51 having high precision. When the metal assisted etching is simply described, first, as illustrated in FIG. 4, the base plate 50 formed by a silicon substrate is provided. Then, as illustrated in FIG. 5, catalytically active metal particles M are attached at positions at which the through holes 51 are formed on the upper surface of the base plate 50. The metal particles M are not particularly limited. For example, it is possible to use Ag (silver), Au (gold), or the like. In addition, it is possible to attach the metal particles M on the base plate 50 by deposition or sputtering. Next, hydrofluoric acid aqueous solution containing hydrogen peroxide water (oxidizing agent) is prepared as etching liquid, and the base plate 50 is immersed in the etching liquid. Then, as illustrated in FIG. 6, an oxidation reaction occurs (SiO₂ is formed) at portions in contact with the metal particles M of the base plate 50, and these portions are dissolved in the etching solution such that, as illustrated in FIG. 7, finally, the through holes 51 that pass through the base plate 50 are formed. According to the metal assisted etching, since it is possible to form the through holes 51 having a diameter approximately equal to a diameter of the metal particles M at positions at which the metal particles M are disposed, it is possible to form the through holes 51 having high accuracy. In addition, since it is possible to form the through holes 51 approximately in a straight shape, it is also possible to increase disposition density of the through holes 51.

So far, the waterproof unit 5 is described. A configuration of the waterproof unit 5 is not limited to the configuration of the embodiment. For example, in the embodiment, as described above, the plurality of through holes 51 are approximately evenly distributed and formed on the first region S1, but a portion having disposition density different from the through holes 51 on the first region S1 may be implemented. For example, as illustrated in FIG. 8, in a plan view, the disposition density of the through holes 51 on a region S12 which is positioned at an edge portion of the opening 221 may be higher than that on a region S11 which is positioned at a center portion of the opening 221 on the first region S1. On the contrary, the disposition density of the through holes 51 on the region S12 may be lower than that on the region S11. As the configuration of FIG. 8, since it is possible to reduce the number of the through holes 51 in the region S11, it is possible to increase the mechanical strength of the region S11. Therefore, even although pressure is received from an outside of the package 2, since it is unlikely that the first region S1 is bent, it is possible to reduce deformation of the through holes 51. As a result, it is possible to more reliably exhibit a function (function that blocks passing of water and permits passing of gas) in each of through holes 51.

### Pressure Sensor Element

As illustrated in FIG. 9, the pressure sensor element 3 includes a substrate 31, a sensor unit 32 provided on the substrate 31, a surrounding structure 33 disposed on an upper surface of the substrate 31, and a hollow portion 34 partitioned by the substrate 31 and the surrounding structure 33.

### Substrate

The substrate 31 is configured by sequentially laminating a first insulating film 312 configured by a silicon oxide film (SiO₂ film), a second insulating film 313 configured by a silicon nitride film (SiN film), and a polysilicon film 314 on a semiconductor substrate 311 that is an SOI substrate (laminated substrate of silicon layer 311a, silicon oxide layer 311b, and silicon layer 311c). However, the semiconductor substrate 311 is not limited to the SOI substrate, and can also use, for example, a silicon substrate. In addition, if it is also possible to exhibit etching resistance and insulation properties with respect to the first insulating film 312 and the second insulating film 313, material is not particularly limited. In addition, the first insulating film 312, the second insulating film 313, and the polysilicon film 314 may be provided, or omitted according to necessity.

In addition, a diaphragm 315 thinner than a periphery portion and to be deformed by receiving the pressure is provided on the semiconductor substrate 311. The diaphragm 315 is formed in a bottom portion of the concave portion 316 by providing the concave portion 316 with a bottom which is opened on a lower surface of the semiconductor substrate 311, and a lower surface (bottom surface of concave portion 316) of the diaphragm 315 becomes a pressure receiving surface 315a.

In addition, a semiconductor circuit (circuit) (not illustrated) electrically connected to the sensor unit 32 is built on the semiconductor substrate 311 and above thereof. Circuit elements such as an active element such as a MOS transistor and the like, a capacitor, an inductor, a resistor, a diode, and a wire, formed according to necessity are included in this semiconductor circuit. However, the semiconductor circuit may also be omitted.

### Sensor Unit

As illustrated in FIG. 10, the sensor unit 32 includes four piezoresistive elements 321, 322, 323, and 324 provided in the diaphragm 315. In addition, the piezoresistive elements 321, 322, 323, and 324 are electrically connected to each other through wires or the like, configure a bridge circuit 320 (wheatstone bridge circuit) illustrated in FIG. 11, and are connected to the semiconductor circuit.

A drive circuit (not illustrated) for supplying a drive voltage AVDC is connected to the bridge circuit 320. Then, the bridge circuit 320 outputs a signal (voltage) in accordance with change of a resistance value of the piezoresistive elements 321, 322, 323, and 324 based on deflection of the diaphragm 315. Therefore, it is possible to detect pressure received by the diaphragm 315 based on the output signal.

For example, each of the piezoresistive elements 321, 322, 323, and 324 is configured by doping (diffusing and injecting) an impurity such as phosphorus and boron into the semiconductor substrate 311 (silicon layer 311c). In addition, for example, the wiring for connecting these piezoresistive elements 321 to 324 is configured by doping (diffusing and injecting) the impurity such as the phosphorus and boron at a concentration higher than that of the piezoresistive elements 321 to 324 into the semiconductor substrate 311 (silicon layer 311c). In FIG. 10, portions illustrated by diagonal lines are the piezoresistive elements, and portions illustrated by white spots are wires.

### Hollow Portion

The hollow portion 34 is partitioned to surround the substrate 31 and the surrounding structure 33. The hollow portion 34 is a sealed space, and functions as a pressure reference chamber corresponding to a reference value of pressure detected by the pressure sensor element 3. In addition, the hollow portion 34 is positioned at an opposite side to the pressure receiving surface 315a of the diaphragm 315, and disposed by overlapping with the diaphragm 315. It is preferable that the hollow portion 34 is in a vacuum state (for example, approximately equal to or less than 10 Pa). With this, it is possible to use the pressure sensor element 3 as a so-called “absolute pressure sensor” for detecting the pressure on the basis of the vacuum, and a highly convenient electronic device 1 can be implemented. However, the hollow portion 34 may also not be the vacuum state if a constant pressure is maintained.

### Surrounding Structure

The surrounding structure 33 partitioning the hollow portion 34 as well as the substrate 31 includes an interlayer insulation film 331, a wiring layer 332 disposed on the interlayer insulation film 331, an interlayer insulation film 333 disposed on the wiring layer 332 and the interlayer insulation film 331, a wiring layer 334 disposed on the interlayer insulation film 333, a surface protection film 335 disposed on the wiring layer 334 and the interlayer insulation film 333, and a sealing layer 336 disposed on the wiring layer 334 and the surface protection film 335.

The wiring layer 332 includes a frame shape wiring portion 3321 disposed to surround the hollow portion 34 and a circuit wiring portion 3329 for configuring the wiring of the semiconductor circuit. Similarly, the wiring layer 334 includes a frame shape wiring portion 3341 disposed to surround the hollow portion 34 and a circuit wiring portion 3349 for configuring the wiring of the semiconductor circuit. Then, the semiconductor circuit is drawn out on an upper surface of the surrounding structure 33 by the circuit wiring portions 3329 and 3349.

In addition, the wiring layer 334 includes a coating layer 3344 positioned at upward (ceiling side) of the hollow portion 34. Then, a plurality of through holes (pores for release etching) 3345 for communicating an inside and outside of the hollow portion 34 are provided on the coating layer 3344. In addition, the sealing layer 336 is disposed on the coating layer 3344, and the through holes 3345 are sealed by the sealing layer 336.

The surface protection film 335 has a function for protecting the surrounding structure 33 from moisture, dirt, and scratches. The surface protection film is disposed on the interlayer insulation film 333 and the wiring layer 334 so as not to block the through holes 3345 of the coating layer 3344.

For example, it is possible to use the insulating film such as the silicon oxide film (SiO₂ film) as the interlayer insulation films 331 and 333 among the surrounding structures 33. In addition, for example, it is possible to use a metal film such as an aluminum film as the wiring layers 332 and 334. In addition, for example, it is possible to use a metal film such as Al, Cu, W, Ti, and TiN, the silicon oxide film, or the like as the sealing layer 336. In addition, for example, it is possible to use the silicon oxide film, the silicon nitride film, a polyimide film, an epoxy resin film, or the like as the surface protection film 335.

So far, the pressure sensor element 3 is described. As illustrated in FIG. 1 and FIG. 2, the pressure sensor element 3 is electrically connected to the IC chip 4 by a bonding wire BW2, and supported in a state suspended on the IC chip 4 (state where floated (separated) from IC chip 4). As described above, by disposing the pressure sensor element 3 in a floating state within the cavity 29, it is unlikely to transmit stress to the pressure sensor element 3 from outside, and it is possible to exhibit excellently pressure sensing accuracy.

In the embodiment, the pressure sensor element 3 is connected to the IC chip 4 through the bonding wire BW2. However, the embodiment is not limited thereto, and the pressure sensor element 3 may be connected to the flexible wire substrate 23 through the bonding wire BW2.

In addition, in the embodiment, as illustrated in FIG. 1, a center O1 of the pressure sensor element 3 is positioned to be deviated from a center O2 of the opening 221 in a plan view. Specifically, in a plan view, the center O1 is positioned by being deviated on an opposite side to the strip 2312 of the flexible wire substrate 23 with respect to the center O2. With this, the degree of freedom in a device design of the electronic device 1 is improved. In addition, it is possible to ensure an installation space of the wire 232 disposed on the base 2311 while achieving miniaturization of the device. Specifically, by this disposition, a region 2311a on a strip 2312 side of the base 2311 can be wider than a region 2311b on an opposite side. On the region 2311a, the wire 232 having an end portion (connection portion with IC chip 4) on the region 2311a and the wire 232 having an end portion on the region 2311b are drawn around, but on the region 2311b, only the wire 232 having an end portion on the region 2311b is drawn around. Therefore, a space for disposing the wire 232 is required on the region 2311a rather than the region 2311b, and the space can be ensured by adopting the above-described configuration. A position of the center O1 of the pressure sensor element 3 is not particularly limited, and may coincide with the center O2 of the opening 221 in a plan view.

### IC Chip

As described above, the IC chip 4 is electrically connected to the flexible wire substrate 23 by the bonding wire BW1, and supported in a state suspended on the flexible wire substrate 23. A semiconductor circuit is provided in the IC chip 4. For example, in the semiconductor circuit within the IC chip 4 and the semiconductor circuit within the pressure sensor element 3, a drive circuit for supplying a voltage to the bridge circuit 320, a temperature compensation circuit for performing temperature compensation according to a temperature of the pressure sensor on output from the bridge circuit 320, an output circuit for converting output from the temperature compensation circuit into a predetermined output format (CMOS, LV-PECL, LVDS, and the like) and outputting the converted result, and the like are included. Disposition of the drive circuit, the temperature compensation circuit, the output circuit, and the like is not particularly limited. For example, the drive circuit may be formed in the semiconductor circuit within the pressure sensor element 3, and the temperature compensation circuit and the output circuit may be formed in the semiconductor circuit within the IC chip 4.

As described above, by providing the IC chip 4 as a separate body from the pressure sensor element 3, it is possible to achieve miniaturization of the pressure sensor element 3, compared to a case where, for example, the IC chip 4 is omitted and all of the above-described circuits are formed within the pressure sensor element 3. In addition, for example, since it is possible to shorten a length of the wire that connects the IC chip 4 and the pressure sensor element 3 compared to a case where the IC chip 4 is disposed outside the package 2, it is unlikely that noises interfere with a signal transmitted through the wire.

In addition, the IC chip 4 is disposed in parallel with (overlapped) the pressure sensor element 3 in a vertical direction (normal direction of diaphragm 315). Therefore, it is possible to suppress expansion in a horizontal direction (in-plane direction of diaphragm 315) of the electronic device 1, and it is possible to achieve miniaturization of the electronic device 1.

So far, the electronic device 1 of the embodiment is described. However, for example, if it is possible to detect the pressure, a configuration of the pressure sensor element 3 is not particularly limited. In addition, for example, the IC chip 4 may also be omitted. In addition, in the embodiment, a configuration in which the pressure sensor element 3 and the IC chip 4 are used as the electronic component accommodated in the package 2 is described. However, the electronic component is not particularly limited thereto. For example, the electronic component may also be a physical quantity sensor such as an accelerometer and an angular velocity sensor, and a vibrator, a microphone, a speaker, or the like used in an oscillator or the like.

### Second Embodiment

Next, an electronic device according to a second embodiment of the invention will be described.

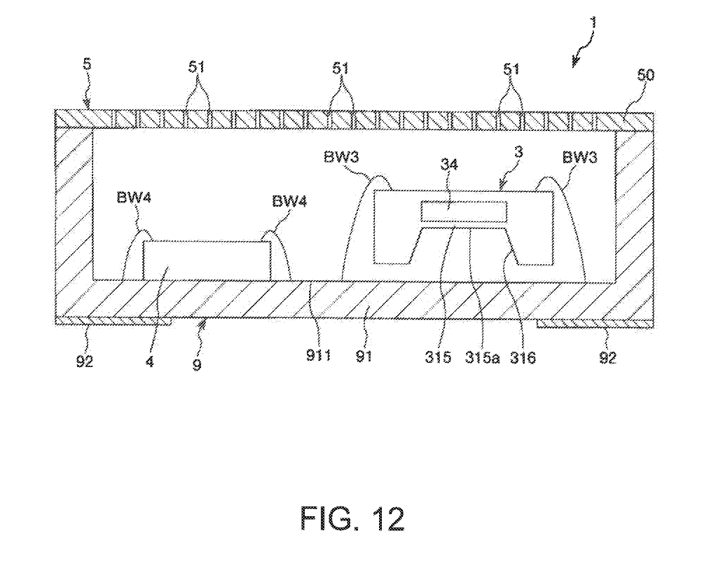

FIG. 12 is a sectional view illustrating an electronic device according to a second embodiment of the invention. Hereinafter, for convenience of explanation, an upper side in FIG. 12 is also referred to as an “upper” and a lower side is referred to as a “lower”.

Hereinafter, for the electronic device of the second embodiment, difference points from the above-described embodiments will be mainly described, and description for the same matters will be omitted.

An electronic device 1 illustrated in FIG. 12 includes a package 9, the pressure sensor element 3 and the IC chip 4 accommodated within the package 9, and the waterproof unit 5 that covers the opening of the package 9. Hereinafter, these parts will be sequentially described.

### Package

The package 9 includes a box shape base 91 including a concave portion 911 of which an upper surface is opened. Constituent material of the base 91 is not particularly limited. However, for example, it is possible to use the same material as the constituent material of the base 21 and the housing 22 in the above-described first embodiment.

### Waterproof Unit

The waterproof unit 5 is fixed (bonded) to the package 9 so as to block the opening of the package 9. With this, it is possible to prevent the passing of water and to permit the passing of gas into the concave portion 911 of the package 9.

### Pressure Sensor Element

The pressure sensor element 3 is accommodated in the concave portion 911, and supported in a state (floated state) suspended on a bottom portion of the concave portion 911 by a bonding wire BW3. In addition, the pressure sensor element is electrically connected to a wire (not illustrated) disposed in the base 91 by the bonding wire BW3.

### IC Chip

The IC chip 4 is fixed on a bottom of the concave portion 911, and disposed in parallel with the pressure sensor element 3. In addition, the IC chip 4 is electrically connected to a wire (not illustrated) provided on the base 91 by a bonding wire BW4, and electrically connected to the pressure sensor element 3 and an external connection terminal 92 provided on a bottom of the base 91 through the wire.

### Third Embodiment

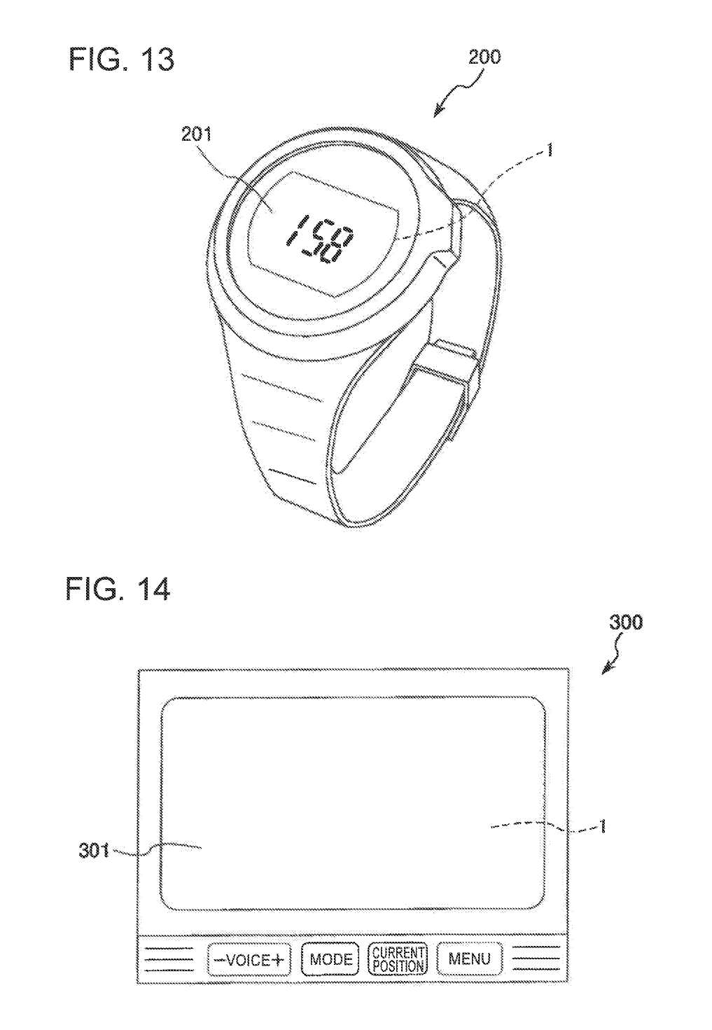

Next, an altimeter according to a third embodiment of the invention will be described. FIG. 13 is a perspective view illustrating an example of the altimeter according to the invention.

As illustrated in FIG. 13, an altimeter 200 can be worn on the wrist like a wristwatch. In addition, the electronic device 1 is mounted inside the altimeter 200, and can display an altitude from the sea level of a current position or atmospheric pressure at the current position on a display unit 201. It is possible to display various items of information such as a current time, a heart rate of a user, and the weather on the display unit 201. Since the altimeter 200 includes the electronic device 1, it is possible for altimeter 200 to have the waterproofness and exhibit high reliability.

In addition to the altimeter 200, for example, the electronic device 1 may be mounted in a wristwatch type depth meter used in free diving or the like. In this case, since it is possible to maintain the waterproofness up to the 10 atm water resistant, that is, a water depth of 100 m, it is possible to exhibit excellent convenience and reliability.

### Fourth Embodiment

Next, an electronic apparatus according to a fourth embodiment of the invention will be described.

FIG. 14 is a front view illustrating an example of the electronic apparatus according to the invention.

The electronic apparatus of the embodiment is a navigation system 300 including the electronic device 1. As illustrated in FIG. 14, the navigation system 300 includes a position information obtaining unit for obtaining position information from map information (not illustrated) and a global positioning system (GPS), an autonomous navigation unit by a gyro sensor, and an acceleration sensor and vehicle speed data, the electronic device 1, and a display unit 301 for displaying predetermined position information or course information.

According to the navigation system 300, it is possible to obtain altitude information in addition to the obtained position information. For example, when traveling on an elevated road indicating the same position as a general road on the position information, the navigation system 300 cannot determine whether a vehicle travels on the general road or the elevated road. Therefore, by detecting change of altitude according to entering from the general road to the elevated road (or vice versa) based on the electronic device 1 mounted on the navigation system 300, it is possible to determine whether traveling on the general road or the elevated road, and it is possible to provide navigation information to users in an actual traveling state. Since the navigation system 300 includes the electronic device 1, it is possible for navigation system 300 to have the waterproofness and exhibit high reliability.

The electronic apparatus including the electronic device according to the invention is not limited to the navigation system. For example, the electronic apparatus can be applied to personal computers, mobile phones, smart phones, tablet computers, timepieces (including smart watch), medical equipment (for example, electronic thermometers, blood pressure monitors, blood glucose meter, electrocardiogram measuring device, ultrasound diagnostic device, and electronic endoscope), various measuring instruments, gauges (for example, gauges of vehicles, aircrafts, and ships), flight simulators, or the like.

### Fifth Embodiment

Next, a moving object according to a fifth embodiment will be described.

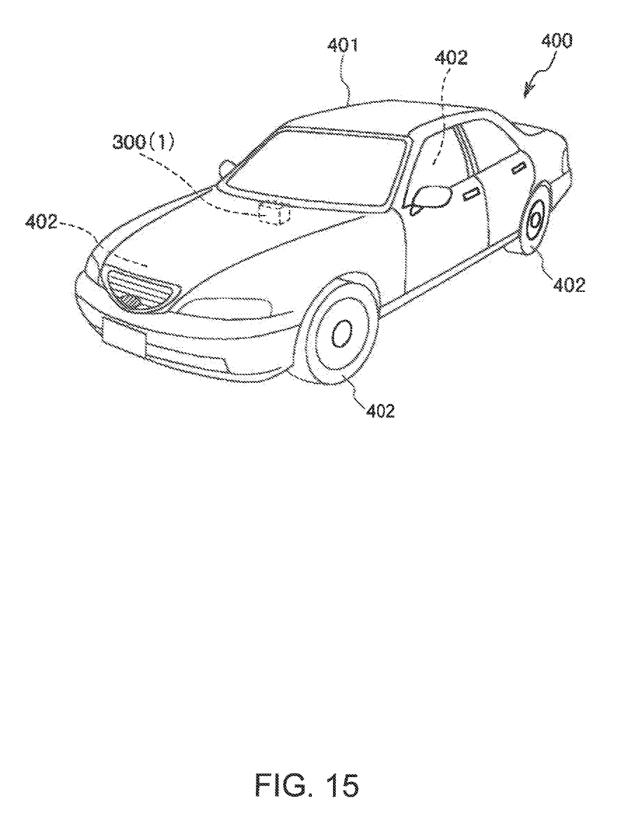

FIG. 15 is a perspective view illustrating an example of the moving object according to the invention.

The moving object of the embodiment is an automobile 400 including the electronic device 1. As illustrated in FIG. 15, the automobile 400 includes a vehicle body 401 and four wheels 402, and is configured to rotate the wheels 402 by power source (engine) (not illustrated) provided in the vehicle body 401. The navigation system. 300 (electronic device 1) is built in the automobile 400. Since the automobile 400 includes the electronic device 1, it is possible for the automobile 400 to have the waterproofness and exhibit high reliability.

So far, the electronic device, the altimeter, the electronic apparatus, and the moving object according to the invention are described based on respective embodiments illustrated. However, the invention is not limited thereto, and a configuration of each part can be replaced with any configuration having the same function. In addition, any other constituents and processes may be added. In addition, embodiments can also be appropriately combined with each other.

The entire disclosure of Japanese Patent Application No. 2016-036339, filed Feb. 26, 2016 is expressly incorporated by reference herein.

What is claimed is:

1. An electronic device comprising:
a package that includes
an opening, and
an accommodation space communicating with the opening;
an electronic component that is disposed in the accommodation space; and
a waterproof unit that is disposed in the package so as to cover the opening,
wherein the waterproof unit is a separate body from the package, blocks passing of liquid, and permits passing of gas from an outside of the package into an inside of the accommodation space.

2. The electronic device according to claim 1,
wherein the waterproof unit includes a through hole that blocks the passing of liquid and permits the passing of gas from the outside of the package into the inside of the accommodation space.

3. The electronic device according to claim 2,
wherein a plurality of through holes are disposed in the waterproof unit, and
wherein disposition density of the through holes positioned on an edge portion of the opening is higher than that of the through holes positioned on a center portion of the opening of the waterproof unit, in a plan view of the opening.

4. The electronic device according to claim 1,
wherein a minimum width of the through hole is equal to or greater than 0.1 μm, and equal to or less than 10 μm.

5. The electronic device according to claim 1,
wherein a center of the electronic component is positioned by being deviated from a center of the opening, in a plan view of the opening.

6. The electronic device according to claim 1,
wherein the package includes
a first member, and
a second member fixed to the first member, and
wherein the waterproof unit is fixed to the package by being pinched between the first member and the second member.

7. The electronic device according to claim 1,
wherein the electronic component is a pressure sensor element.

8. An altimeter comprising the electronic device according to claim 1.

9. An altimeter comprising the electronic device according to claim 2.

10. An altimeter comprising the electronic device according to claim 3.

11. An altimeter comprising the electronic device according to claim 4.

12. An altimeter comprising the electronic device according to claim 5.

13. An electronic apparatus comprising the electronic device according to claim 1.

14. An electronic apparatus comprising the electronic device according to claim 2.

15. An electronic apparatus comprising the electronic device according to claim 3.

16. An electronic apparatus comprising the electronic device according to claim 4.

17. A moving object comprising the electronic device according to claim 1.

18. A moving object comprising the electronic device according to claim 2.

19. A moving object comprising the electronic device according to claim 3.

20. A moving object comprising the electronic device according to claim 4.
